(19) United States
(12) Patent Application Publication
(10) Pub. No.: US 2022/0129748 A1
(43) Pub. Date: Apr. 28, 2022

(54) SYSTEM AND METHOD FOR MONITORING A MACHINE

(71) Applicant: N Point Infotech Co., Ltd., New Taipei City (TW)

(72) Inventor: Morris Shih, New Taipei City (TW)

(73) Assignee: N POINT INFOTECH Co., Ltd., New Taipei City (TW)

(21) Appl. No.: 17/158,541

(22) Filed: Jan. 26, 2021

(30) Foreign Application Priority Data
Oct. 28, 2020 (TW) 109137390

(51) Int. Cl. G06N 3/08; G06K 9/62

(52) U.S. Cl. CPC G06N 3/08; G06K 9/6215; G06K 9/6256

(57) ABSTRACT

A system for monitoring a machine includes a transducer mounted to the machine, and a processing unit coupled to the transducer. The transducer converts a sound produced by the machine during operation into a to-be-tested dataset. The processing unit receives the to-be-tested dataset from the transducer, performs time-frequency analysis on the to-be-tested dataset to generate a to-be-tested spectrogram based on the to-be-tested dataset, inputs the to-be-tested spectrogram to an analysis model of a deep neural network to obtain an analysis result, determines whether the machine is abnormal based on the analysis result, and outputs an abnormal signal when it is determined that the machine is abnormal.

### CROSS-REFERENCE TO RELATED APPLICATION

This application claims priority to Taiwanese Invention Patent Application No. 109137390, filed on Oct. 28, 2020.

### FIELD

The disclosure relates to a system and a method for monitoring a machine, and more particularly to a system and a method for monitoring a machine according to a sound produced by operation of the machine.

### BACKGROUND

Highly automated machinery is becoming increasingly widespread. However, all machines may potentially malfunction after extended use. If a malfunction of a machine cannot be detected and resolved in time, it could negatively affect efficiency of the machine, e.g., production yield for factory machinery, and decrease useful lifespan of the machine.

A conventional method for detecting an abnormal state of a machine requires disassembling the machine in order to identify malfunctioning components. Therefore, most factory machinery must either rely on routine service or wait until the machine malfunctions before calling for repairs.

The problem with routine service is that a machine may be able to operate with a defective component for some time before the defect is found through servicing. During this period of operation, the defective component may cause damage to other components within the machine, thereby increasing the cost of repairing the machine. Furthermore, if the defective component is not identified during servicing and the machine is left to operate until it ultimately malfunctions, the cost of repair would increase significantly.

### SUMMARY

Therefore, an object of the disclosure is to provide a system and a method for monitoring a machine that can alleviate at least one of the drawbacks of the prior art.

According to one aspect of the disclosure, a system for monitoring a machine includes a transducer and a processing unit. The transducer is configured to be mounted to a target machine and to convert a sound produced by the target machine during operation into a to-be-tested dataset. The processing unit is coupled to the transducer to receive the to-be-tested dataset, and is configured to perform time-frequency analysis on the to-be-tested dataset to generate a to-be-tested spectrogram based on the to-be-tested dataset, to input the to-be-tested spectrogram to an analysis model of a deep neural network to obtain an analysis result, to determine whether the target machine is abnormal based on the analysis result, and to output an abnormal signal when it is determined that the target machine is abnormal.

According to another aspect of the disclosure, a method for monitoring a machine is to be implemented by a processing unit, and includes steps of receiving a to-be-tested dataset that is related to a sound produced by operation of a target machine, performing time-frequency analysis on the to-be-tested dataset to generate a to-be-tested spectrogram based on the to-be-tested dataset, inputting the to-be-tested spectrogram to an analysis model of a deep neural network to obtain an analysis result, determining whether the target machine is abnormal based on the analysis result, and outputting an abnormal signal when it is determined that the target machine is abnormal.

### BRIEF DESCRIPTION OF THE DRAWINGS

Other features and advantages of the disclosure will become apparent in the following detailed description of the embodiment(s) with reference to the accompanying drawings, of which:

FIG. 1 is a block diagram of a system for monitoring a machine according to an embodiment of the disclosure;

FIG. 2 is a flow chart illustrating a training procedure for training an analysis model used to determine whether a machine is abnormal in a method for monitoring a machine according to an embodiment of the disclosure;

FIG. 3 is a flow chart illustrating a procedure for determining a threshold value used in the method for monitoring a machine according to an embodiment of the disclosure; and

FIG. 4 is a flow chart illustrating a monitoring procedure of the method for monitoring a machine according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

Throughout the disclosure, the term “coupled to” may refer to a direct connection among a plurality of electrical apparatus/devices/equipments via an electrically conductive material (e.g., an electrical wire), or an indirect connection between two electrical apparatus/devices/equipments via another one or more apparatus/device/equipment, or wireless communication between two electrical apparatus/devices/equipments via a communication network.

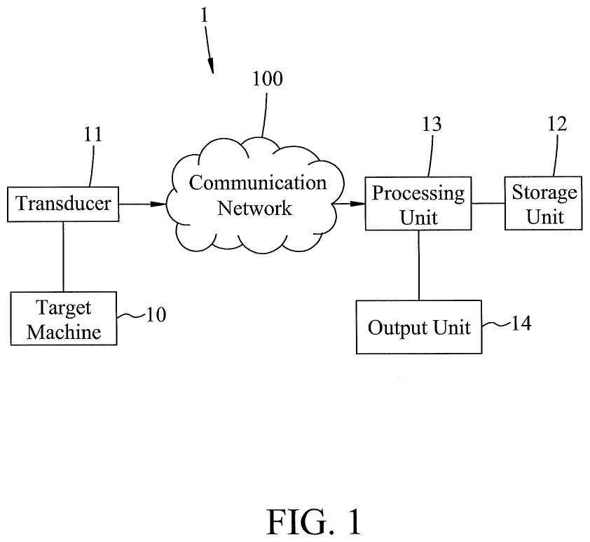

Referring to FIG. 1, an embodiment of a system 1 for monitoring a machine includes a transducer 11, a storage unit 12, a processing unit 13 and an output unit 14.

The transducer 11 (e.g., a microphone) is mounted to a target machine 10 (e.g., a machine tool) and is configured to convert a sound produced by operation of the target machine 10 into an audio dataset. In this embodiment, the transducer 11 is configured to convert a sound having an audio frequency between 20 Hz and 48 kHz or above 48 kHz. Since the system 1 may be used to monitor the target machine 10 over a long period of time, the transducer 11 may be configured to capture and convert, for example, 10 seconds of sound into an audio dataset every one minute in order to save power consumption. It should be noted that this disclosure is not limited to the above-mentioned configuration of the transducer 11.

The storage unit 12 is, for example but not limited to, electrically-erasable programmable read-only memory (EEPROM), a hard disk, a solid-state drive (SSD), or a non-transitory storage medium (e.g., secure digital (SD) memory, flash memory, etc.). The storage unit 12 is electrically connected to the processing unit 13, and stores instructions that are executable by the processing unit 13 to implement a method for monitoring a machine. Examples of the instructions may include any suitable types of code, such as source code, compiled code, interpreted code, executable code, static code, dynamic code, object-oriented code, visual code, and the like. In this embodiment, the storage unit 12 further stores a plurality of training datasets that are related to sounds produced by the target machine 10 or by another machine of a same type as the target machine 10 during normal operation. Specifically, the plurality of training datasets may be generated by the transducer 11 capturing sounds produced by the target machine 10 at different time points during normal operation or produced by one or more other machines of the same type as the target machine 10 at different time points during normal operation, and then converting the sounds thus captured into a plurality of audio datasets that serve as the plurality of training datasets, respectively. It should be noted that the sounds produced during normal operation of said machine(s) and captured by the transducer 11 may have an audio frequency between 20 Hz and 48 kHz or above 48 kHz.

For example, the processing unit 13 is a microcontroller including, but not limited to, a single core processor, a multi-core processor, a dual-core mobile processor, a microprocessor, a microcontroller, a digital signal processor (DSP), a field-programmable gate array (FPGA), an application specific integrated circuit (ASIC), a radio-frequency integrated circuit (RFIC), etc. The processing unit 13 is configured to wirelessly communicate with the transducer 11 through a communication network 100 and is coupled to the storage unit 12. In some embodiments, the processing unit 13 may be electrically connected to the transducer 11 through a wired connection. In some embodiments, the processing unit 13 and the storage unit 12 are included in a single computing device (e.g., a server, a personal computer, a laptop computer, a tablet computer, etc.). In some embodiments, the processing unit 13 is included in one server while the storage unit 12 is included in another server (e.g., a database server) that communicates with said one server through a communication network.

The output unit 14 is coupled to the processing unit 13. In some embodiments, the output unit 14 may be embodied using a display device or a speaker that is electrically connected to and controlled by the processing unit 13. In some embodiments, the output unit 14 may be embodied using a personal electronic device (e.g., a smart phone, a tablet computer, etc.) communicating with the processing unit 13 through a communication network to receive a signal therefrom.

The transducer 11 and the processing unit 13 may each include a communication component (e.g., a radio-frequency integrated circuit (RFIC), a short-range wireless communication module supporting a short-range wireless communication network using a wireless technology of Bluetooth® and/or Wi-Fi, etc., a mobile communication module supporting telecommunication using Long-Term Evolution (LTE), the third generation (3G) and/or fifth generation (5G) of wireless mobile telecommunications technology, or the like), allowing the transducer 11 and the processing unit 13 to wirelessly communicate with each other.

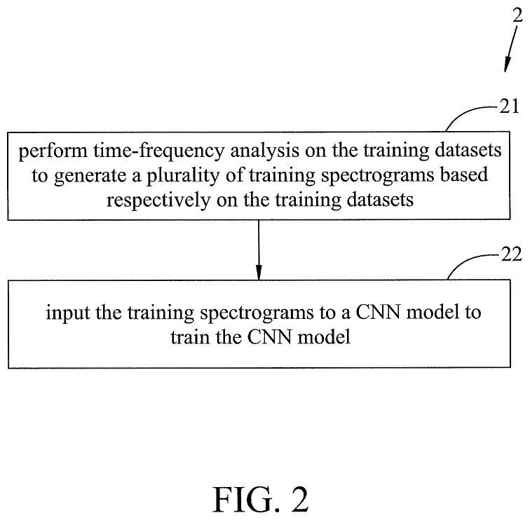

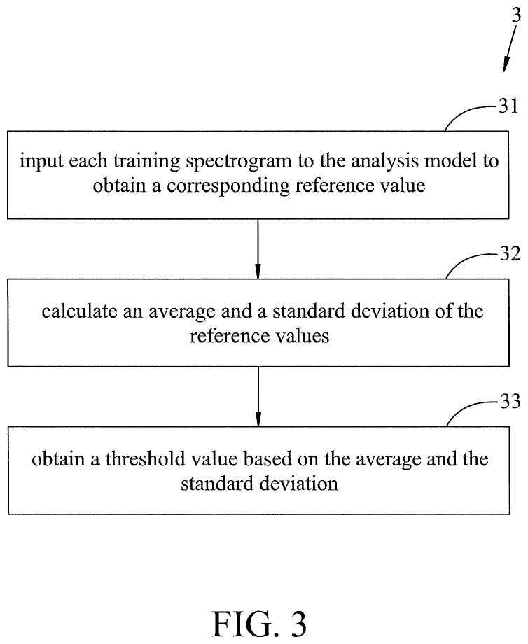

Further referring to FIGS. 2 to 4, the method for monitoring a machine includes a training procedure 2, a threshold-determining procedure 3 and a monitoring procedure 4.

In step 21 of the training procedure 2, the processing unit 13 performs time-frequency analysis on the plurality of training datasets to generate a plurality of training spectrograms based respectively on the plurality of training datasets.

Then, in step 22 of the training procedure 2, the processing unit 13 inputs the plurality of training spectrograms to a convolutional neural network (CNN) model to train the CNN model. In some embodiments, the CNN model may be a pre-trained model (e.g., Autoencoder, Densenet, Xception and Resnet). The CNN model that has been trained using the plurality of training spectrograms will be used as an analysis model of a deep neural network in the monitoring procedure 4 for determining whether the target machine 10 is abnormal. It should be noted that an output of the analysis model is a value ranging from 0 to 100 and indicating a probability of an input spectrogram into the analysis model belonging to a class defined by the plurality of training spectrograms (a class of normal operation). In other words, the output of the analysis model means a similarity between the input spectrogram and the group of training spectrograms. Specifically, the greater the value of the output of the analysis model, the more similar the input spectrogram is to the group of training spectrograms, which means that a sound related to the input spectrogram is more similar than not to the sounds related to the group of training spectrograms.

After the analysis model is built, the processing unit 13 implements the threshold-determining procedure 3 that includes steps 31-33 to determine a threshold value to be used in the monitoring procedure 4.

In step 31, for each of the plurality of training spectrograms, the processing unit 13 inputs the training spectrogram to the analysis model to obtain a reference value that indicates similarity between the training spectrogram and the group of training spectrograms.

Then, the processing unit 13 calculates an average and a standard deviation of the reference values that are respectively obtained in step 31 for the plurality of training spectrograms (step 32), and obtains a threshold value based on the average and the standard deviation (step 33). For example, in step 33, the processing unit 13 subtracts the standard deviation from the average to obtain a difference as the threshold value.

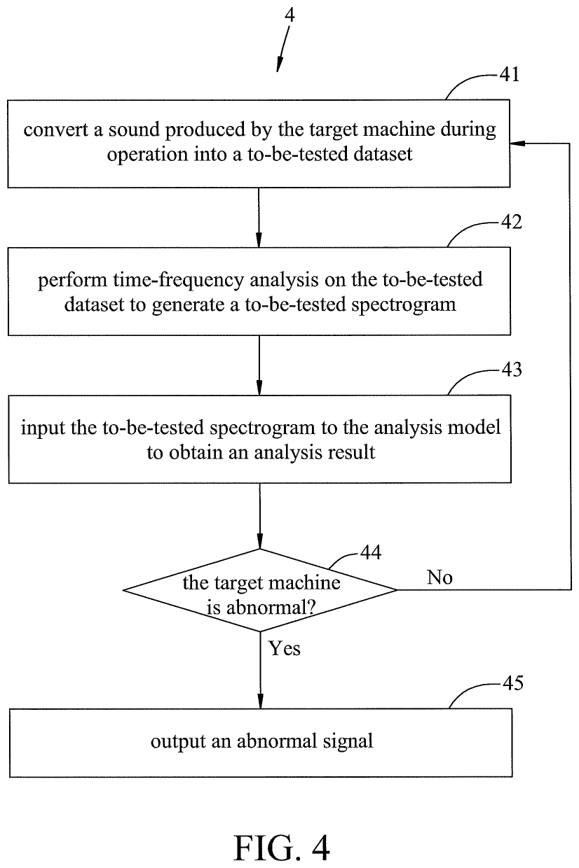

Referring to FIG. 4, the monitoring procedure 4 of the method for monitoring a machine includes steps 41-45.

In step 41, the transducer 11 captures a sound produced during operation of the target machine 10, and then converts the sound thus captured into a to-be-tested dataset. The transducer 11 then transmits the to-be-tested dataset to the processing unit 13 for the following analysis.

Upon receiving the to-be-tested dataset from the transducer 11, in step 42, the processing unit 13 first performs time-frequency analysis on the to-be-tested dataset to generate a to-be-tested spectrogram based on the to-be-tested dataset. In some embodiments, in order to reduce data values that are related to ambient noise in the to-be-tested dataset, the processing unit 13 may further perform exponentiation on the to-be-tested dataset before performing the time-frequency analysis on the to-be-tested dataset. Accordingly, data values that are related to a part of the sound having a relatively greater volume (e.g., greater than an average volume of the sound) will be increased, while data values that are related to a part of the sound having a relatively lower volume (e.g., lower than the average volume) will be decreased, which alleviates effects of ambient noise on a result of the time-frequency analysis. In some embodiments, the data values that are related to the part of the sound having a volume greater than the average volume are each multiplied by a value greater than one, while the data values that are related to the part of the sound having a volume lower than the average volume are each multiplied by a value smaller than one.

In step 43, the processing unit 13 inputs the to-be-tested spectrogram to the analysis model to obtain an analysis result. Specifically, the output of the analysis model with the to-be-tested spectrogram serving as the input is a similarity index that indicates similarity between the to-be-tested spectrogram and the group of training spectrograms and that serves as the analysis result.

In step 44, the processing unit 13 determines whether the target machine 10 is abnormal based on the analysis result. Specifically, the processing unit 13 compares the analysis result (i.e., the similarity index) to the threshold value, and determines that the target machine 10 is abnormal when the similarity index is less than the threshold value and determines that the target machine 10 is normal when otherwise. The flow goes to step 45 when it is determined that the target machine 10 is abnormal, and goes back to step 41 when otherwise.

In step 45, the processing unit 13 outputs an abnormal signal indicating that the target machine 10 is abnormal. Specifically, the processing unit 13 may transmit the abnormal signal to the output unit 14 so as to control the output unit 14 to output a warning in a form of a text message displayed on a display device of the output unit 14 or a sound outputted by a speaker of the output unit 14.

In summary, the system 1 and the method for monitoring a machine uses the transducer 11 to capture the sound produced by the target machine 10 and to convert the sound into the to-be-tested dataset, and then the processing unit 13 performs time-frequency analysis of the to-be-tested dataset to generate the to-be-tested spectrogram and inputs the to-be-tested spectrogram to the analysis model to obtain the analysis result (similarity index) which is then used to determine whether the target machine 10 is abnormal. By virtue of the system 1 and the method, an abnormal state of the target machine 10 can be detected without disassembling the target machine 10. Further, the transducer 11 is capable of capturing and converting a sound having an audio frequency between 20 Hz and 48 kHz or above 48 kHz according to embodiments of this disclosure, and the analysis model can be used to analyze a spectrogram related to a sound having relatively higher audio frequency. Therefore, the system 1 and the method can accurately detect whether the target machine 10 has an abnormality that may produce a high-frequency sound which is not perceivable by humans.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A system for monitoring a machine, comprising:
a transducer configured to be mounted to a target machine and to convert a sound produced by the target machine during operation into a to-be-tested dataset; and
a processing unit coupled to said transducer to receive the to-be-tested dataset, and configured to
perform time-frequency analysis on the to-be-tested dataset to generate a to-be-tested spectrogram based on the to-be-tested dataset,
input the to-be-tested spectrogram to an analysis model of a deep neural network to obtain an analysis result,
determine whether the target machine is abnormal based on the analysis result, and
output an abnormal signal when it is determined that the target machine is abnormal.

2. The system of claim 1, wherein said processing unit is further configured to, before performing the time-frequency analysis on the to-be-tested dataset, perform exponentiation on the to-be-tested dataset.

3. The system of claim 1, further comprising a storage unit being coupled to said processing unit and storing a plurality of training datasets that are related to sounds produced by one of the target machine and another machine of a same type as the target machine during normal operation,
wherein said processing unit is further configured to perform time-frequency analysis on the plurality of training datasets to generate a plurality of training spectrograms based respectively on the plurality of training datasets, to input the plurality of training spectrograms to a convolutional neural network (CNN) model to train the CNN model, and to use the CNN model that has been trained using the plurality of training spectrograms as the analysis model.

4. The system of claim 3, wherein said processing unit is further configured to:
for each of the plurality of training spectrograms, input the training spectrogram to the analysis model to obtain a reference value that indicates similarity between the training spectrogram and the plurality of training spectrograms as a group;
calculate an average and a standard deviation of the reference values obtained respectively for the plurality of training spectrograms, and
obtain a threshold value based on the average and the standard deviation,
wherein, in inputting the to-be-tested spectrogram to the analysis model, said processing unit is configured to input the to-be-tested spectrogram to the analysis model to obtain a similarity index that indicates similarity between the to-be-tested spectrogram and the plurality of training spectrograms as a group and that serves as the analysis result,
wherein, in determining whether the target machine is abnormal, said processing unit is configured to determine that the target machine is abnormal when the similarity index is less than the threshold value.

5. The system of claim 4, wherein said processing unit is configured to subtract the standard deviation from the average to obtain a difference as the threshold value.

6. The system of claim 1, wherein said transducer is configured to convert a sound having an audio frequency between 20 Hz and 48 kHz.

7. The system of claim 1, wherein said transducer is configured to convert a sound having an audio frequency above 48 kHz.

8. A method for monitoring a machine, the method to be implemented by a processing unit and comprising steps of:
receiving a to-be-tested dataset that is related to a sound produced by a target machine during operation;
performing time-frequency analysis on the to-be-tested dataset to generate a to-be-tested spectrogram based on the to-be-tested dataset;
inputting the to-be-tested spectrogram to an analysis model of a deep neural network to obtain an analysis result;
determining whether the target machine is abnormal based on the analysis result; and
outputting an abnormal signal when it is determined that the target machine is abnormal.

9. The method of claim 8, further comprising, before the step of performing time-frequency analysis on the to-be-tested dataset, a step of performing exponentiation on the to-be-tested dataset.

10. The method of claim 8, further comprising steps of:
receiving a plurality of training datasets that are related to sounds produced by one of the target machine and another machine of a same type as the target machine during normal operation;
performing time-frequency analysis on the plurality of training datasets to generate a plurality of training spectrograms based respectively on the plurality of training datasets;
inputting the plurality of training spectrograms to a convolutional neural network (CNN) model to train the CNN model; and
using the CNN model that has been trained using the plurality of training spectrograms as the analysis model.

11. The method of claim 10, further comprising steps of:
for each of the plurality of training spectrograms, inputting the training spectrogram to the analysis model to obtain a reference value that indicates similarity between the training spectrogram and the plurality of training spectrograms as a group;
calculating an average and a standard deviation of the reference values; and
obtaining a threshold value based on the average and the standard deviation,
wherein the step of inputting the to-be-tested spectrogram to an analysis model is to obtain a similarity index that indicates similarity between the to-be-tested spectrogram and the plurality of training spectrograms as a group and that serves as the analysis result,
wherein the step of determining whether the target machine is abnormal is to determine that the target machine is abnormal when the similarity index is less than the threshold value.

12. The method of claim 11, wherein the step of obtaining a threshold value includes subtracting the standard deviation from the average to obtain a difference as the threshold value.

13. The method of claim 8, to be implemented further by a transducer mounted to the target machine, the method further comprising steps of:
converting, by transducer, the sound produced by the target machine during operation into the to-be-tested dataset; and
transmitting, by transducer, the to-be-tested dataset to the processing unit.

14. The method of claim 8, wherein, in the step of receiving a to-be-tested dataset, the to-be-tested dataset is related to the sound that is produced by the target machine during operation and that has an audio frequency between 20 Hz and 48 kHz.

15. The method of claim 8, wherein, in the step of receiving a to-be-tested dataset, the to-be-tested dataset is related to the sound that is produced by the target machine during operation and that has an audio frequency above 48 kHz.
